(19) United States
(12) Patent Application Publication
(10) Pub. No.: US 2008/0204686 A1
(43) Pub. Date: Aug. 28, 2008

(54) Mask Structure for Manufacturing an Integrated Circuit by Photolithographic Patterning

(76) Inventors: Wolfgang Henke, Radebeul (DE); Mario Hennig, Dresden (DE); Rainer Pforr, Dresden (DE)

Correspondence Address: SLATER & MATSIL, L.L.P., 17950 PRESTON ROAD, SUITE 1000, DALLAS, TX, 75252, US

(21) Appl. No.: 12/037,795

(22) Filed: Feb. 26, 2008

(30) Foreign Application Priority Data
Feb. 26, 2007 (DE) 10 2007 009 265.4

(51) Int. Cl. G03B 27/42; G03F 1/14; G03F 7/26

(52) U.S. Cl. 355/53; 430/5; 430/311

(57) ABSTRACT

Photolithography using polarized light is disclosed. For example, a method includes transmitting the light through a mask having a first area with a first class of patterns and a second area with a second class of patterns thereby generating a virtual image. The virtual image is exposed into a resist layer. The polarization of the light passing the first area is modified while the light passing the mask.

This application claims priority to German Patent Application 10 2007 009 265.4, which was filed Feb. 26, 2007 and is incorporated herein by reference.

### TECHNICAL FIELD

The invention relates to a method and a device for manufacturing an integrated circuit by photolithographic patterning in semiconductor technology especially in photolithography by use of polarized light. It also relates to a photomask, a method for making such a photomask and a mask blank. It can be used in semiconductor technology.

### BACKGROUND

Photolithographic techniques are common in making integrated circuits. An image of the pattern, arranged on a photomask, is projected on a resist covering a wafer. The exposed image will be developed and is used as a mask to generate the pattern on the wafer.

The technological challenge is directed to smaller dimensions. The decrease of the smallest realizable patterns, so called critical dimension or CD, requires an increase of the resolution of the optical system. The resolution of an optical system increases by shortening the wavelength of the used light. Currently used photolithographic light sources are working at a wavelength of λ equal 193 nm. The applicability of such light for lithographic patterning with typical dimensions down to about 80 nm is established.

Polarized light is increasingly used for further improving of patterning, e.g., of array patterns in making semiconductor memories. Especially for the realization of high density packed patterns at critical dimensions below about 70 nm the advantages of polarized light are verified.

The lithography of patterns with a half pitch smaller than about 60 nm is assumed to require the use of linear polarized light for the exposure process. The reason is, that the use of polarized light for the transfer of small half pitch patterns results in a significant increase of the contrast within the resist layer and in an edge sharpness depending on the orientation of the patterns relative to the polarization of the light used. That contrast increase and edge sharpening is a basic condition for fabricating these critical lithographic patterns with sufficient process windows.

With respect to the increasing resolution requirements and the decreasing dimensions of the patterns manufacturers of lithographic tools currently provide illuminating systems, which enable the adjustment of the polarization of the used light. There are dipole illuminating systems as well as bilinear systems for cross quad exposure. In this case two illumination poles respectively own the same polarization.

The progress in the development of illuminating systems was not accompanied by accordant developments in optical systems. There are many sources of birefringence within the lens systems which induce considerable deformation of the wave front when using linearly polarized light, so called polarization aberrations, which may cause relevant image defects. Well known effects of this are astigmatism and spherical aberration, limiting the use of linear polarized light in photolithography and impacting the quality of the resist patterns.

Especially the image transfer of patterns with a larger pitch than those of array patterns of a semiconductor memory, e.g., isolated or semi isolated patterns impacts the image quality resulting in line width difference between vertically and horizontally oriented lines and the variation of this difference as a function of the defocus.

These effects result on the one hand from residual aberrations from the lens (associated with polarized light) on the other hand from aberrations of the mask itself.

They are observed even for patterns with uncritical dimension, for example, about 200 nm, when using polarized light, while a more constant line width stability is observed when using non-polarized light.

Furthermore, the use of linear polarized light can result in high horizontal-vertical differences in CD and a high variation of the CD over the image area and as a function of defocus.

Beside polarization aberrations of the lens system, wave guide effects from the mask patterns may result in phase shifts of the wave front running out of the mask. The phase shift variations result from differences between phases of zero and higher orders of diffraction in dependence of the direction of polarization and of the orientation of the mask patterns relative to the direction of polarization.

As an example the phase shift for patterns of about 200 nm isolated lines on a chrome mask for the orientations perpendicular and parallel to the orientation of the polarization relative to the radiation angle can exhibit dramatic different curve progression. The phase shift of both orientations may cause the astigmatism effect to be inherent to the mask.

The above discussed effects may add onto or cancel out each other and will result in a high offset between horizontal and vertical oriented lines as well as high CD variation over the image area and as a function of defocus.

### BRIEF DESCRIPTION OF THE DRAWINGS

The drawings show:

FIG. 1 shows a photomask with opaque absorber patterns and an additional chiral layer by subsequent local removal of the chiral layer for transforming linear into circular polarization;

FIG. 2 shows a photomask with opaque absorber patterns, a chiral layer as well as a nonchiral, phase shifting pattern for compensation of the phase shift of the chiral layer differing from λ/4;

FIG. 3 shows a photomask with phase shifting absorber patterns, a chiral layer and a transparent achiral phase shifting layer;

FIG. 4 shows a photomask with a chiral layer, located between the glass carrier of the mask and the absorber patterns for transformation of linear into circular polarization; and

FIG. 5 shows a photomask with a chiral layer, located between the glass carrier of the mask and the absorber patterns for transformation of linear into elliptical polarization.

### DETAILED DESCRIPTION OF ILLUSTRATIVE EMBODIMENTS

A first example of an implementation of a method for error correction in photo lithography by polarized light is described. The polarization is modified inside the optical path within bright areas between absorber patterns suffering harms in their imaging quality during lithography by polarized light. Within these areas the linear polarization is transformed into circular or elliptical polarization.

A second implementation of an embodiment of the invention includes a photolithographic system for image error correction by use of polarized light. The system comprises a source of light, optical elements for homogenization, linear polarization and projection of the light, a photomask device as well as optical elements for imaging on a resist to be patterned. Within the optical path chiral, i.e., birefringent patterns are arranged for correction of image errors resulting from polarization by means of their dimensions (e.g., layer thickness, coefficient of birefringence). These additional chiral patterns within the optical path realize a phase shift of λ/4 resp. of near λ/4 between the axes of birefringence. A deviation in the phase shift from the value of λ/4 may be used to correct the predetermined phase shift resulting from polarization aberrations of the lens system.

A third implementation of an embodiment of the invention includes a method to photolithographically transfer patterns to a semiconductor substrate. The mask patterns may be separated in at least two classes. One aspect of this invention is to maintain linear polarization of light around a first class of patterns requiring the polarization for correct imaging because of the above discussed effects.

For at least a second class of patterns on the mask the errors caused by use of linear polarized light will be minimized or eliminated by applying depolarizing layers around these patterns. These imaging errors result from imperfections of the lens system when using polarized light, as well as from mask effects and will be avoided by destruction, transformation or modification of the polarization for exactly this class of objects.

For lithographically critical patterns of, e.g., semiconductor memories the area outside the arrays will be covered by a depolarizing layer while the array area will stay free of it. The polarized light within the array will then help to improve the imaging while avoiding the imaging errors.

According to a further implementation an embodiment of the invention includes a photomask for the lithography by polarized light which corrects for errors in imaging resulting from polarization. The mask includes at least two classes of patterns differing in their imaging properties respectively when using polarized light. A chiral layer is arranged within the bright areas between mask structures patterns suffering imaging errors by polarization. That chiral layer is designed with a thickness to transform the linear polarized light into circular or elliptical polarized light. Circular or elliptical polarized light performs an imaging like non polarized light and does not create the typical aberrations in imaging for this class of patterns.

These chiral layers are not present within another area of the mask containing patterns of a different class requiring polarized light for realization of contrast and image definition.

A further example of an embodiment of the invention includes the method of manufacturing of a photolithographic mask for the correction of imaging errors resulting from polarization aberrations for mask patterns of different classes. The different mask patterns are characterized by their differing critical dimensions (CD), i.e., half pitch period, as well as by the orientation of the periodical patterns relatively to the orientation of the polarized light. The bright areas of the mask areas containing patterns of the class suffering from polarization aberrations will be covered by chiral layers. The phase shift between the optical axes of these layers has to be ≅λ/4.

The chiral layers will be applied by a deposition process after the usual mask manufacturing process with subsequent local removal.

A further implementation includes the deposition of the chiral layer during the manufacturing of the mask blank between the glass carrier and the absorber layer. After mask patterning, the chiral layer will be removed within the areas containing patterns of the class requiring polarized light for realization of sufficient contrast and edge focusing.

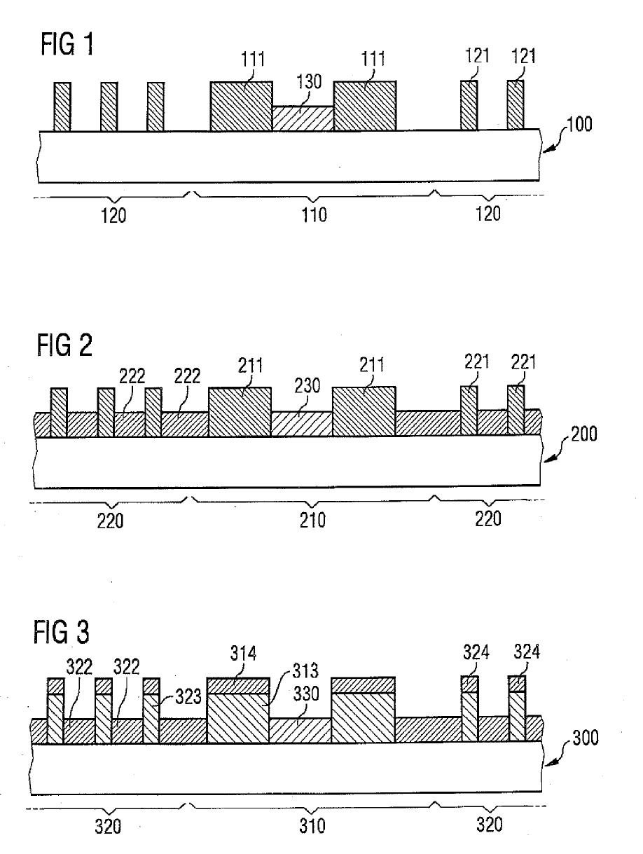

FIG. 1 shows a photolithographic mask for photolithography by use of polarized light, which allows the correction of aberrations from polarization while maintaining the effects of the use of linear polarized light for a certain class of the mask patterns. On a mask glass carrier 100 different areas of absorber patterns 110, 120, representing different classes of objects on the mask are arranged. The absorber patterns 111 of the area 110 would cause strong aberrations within the photoresist due to their characteristic dimensions and their orientation relative to the direction of polarization. On the other hand, the absorber patterns 121 of the areas 120 can be transferred into the photoresist with an acceptable process window due to their characteristic dimensions only by means of linear polarized light. Within the areas 110 a chiral layer 130 is introduced. This layer 130 is arranged in a manner working like a λ/b 4-layer. For this purpose the thickness and the material of the layer must be carefully chosen.

Further criteria for the choice of materials are the compatibility of the material and/or its processing using conventional mask processes, a sufficient transmission as well as radiation resistance for the relevant wavelength. The birefringence of the material should not vary much in the angle range used in the exposure process. Available materials are in particular, but not limited to, BaF, MgF₂ and CdSe.

There are however also other materials conceivable if they correspond to the requirements specified above. The birefringent layer is applied after provision of the absorber patterns in a following deposition step for the entire mask surface and later removed within the areas 120.

FIG. 2 shows the areas 210 and 220 on the mask glass carrier the areas with different pattern classes. The absorber patterns consist of an opaque material, e.g., Cr. The chiral layer 230 within the area 210 has a thickness to cause a phase shift of λ/4 plus a deviation δ between the axes of birefringence. That deviation δ results from the fact that the imaging lens system itself provides aberrative components with the formation of the wave front reducing the imaging quality. The amount of the phase shift of the chiral layer 230 deviating from λ/4 compensates exactly the error amount determined before in the optical system. The bright areas within the areas 220 of the mask containing objects 221 of the class requiring polarized light for the photolithographic patterning are covered with a transparent, achiral, phase shifting layer 222 in this case. The thickness of this layer 222 is selected to cause exactly the same phase shift as the chiral layer 230 within the area 210.

According to FIG. 3 the absorber patterns 313, 323 of the mask carrier 300 comprises a semitransparent phase shifting material, e.g., MoSi, causing a phase shift between bright and dark areas of λ/2. The bright areas between the absorber patterns 313 within the area 310 are covered by a chiral layer 330. In order to maintain the phase shift of λ/2 caused by the absorber patterns 313, 323 a transparent, achiral, phase shifting layer 314, 324 have to cover these absorber patterns, too. The thickness of this layer 314, 324 is selected to compensate the phase shift caused by the layer 330.

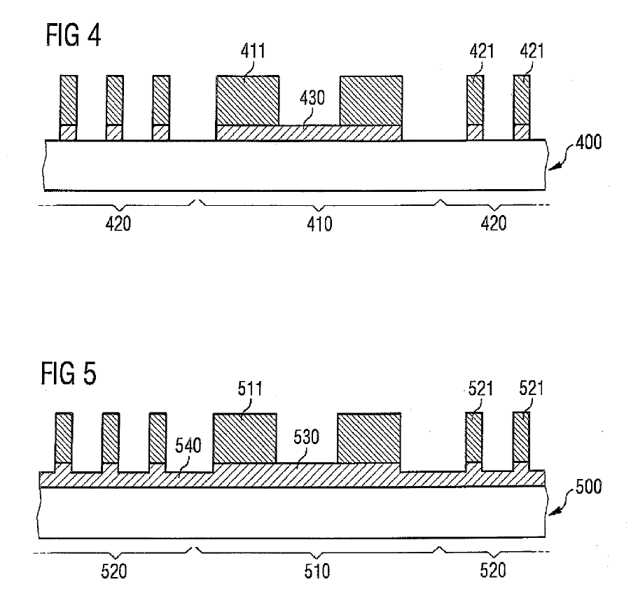

FIG. 4 shows a further embodiment of the photomask. The chiral layer 430 was applied during the making of the mask blank between the glass carrier 400 and the absorber patterns 411, 421 within the areas 410, 420. The chiral layer is removed within the areas 420 containing the class of patterns requiring linear polarized light for photolithographic imaging. The removal may be performed by, e.g., etching.

According to FIG. 5 a chiral layer 530 is applied onto the glass carrier 500. The thickness of this layer has to be selected to cause a phase shift of [symbol] 4 [symbol] δ between the axes of birefringence. The deviation δ from λ/4 serves again as the compensation of the previously determined phase shift resulting from the aberrative components of the imaging system. After applying the layer 530 the mask patterns 511, 521 within the mask areas 510, 520 will be applied. Within the areas 520, requiring linear polarized light for the imaging step, the layer 530 is selectively removed whereas a chiral layer 540 corresponding to the deviation of the phase shift from λ/4 within the areas 510 remains.

The above description of the invention in detail and with reference to embodiments has been given by way of example. From the disclosure given, a person skilled in the art will not only understand the embodiments given for the present invention but also will find various modifications to the methods and patterns disclosed. Accordingly it is intended to cover all the modifications and changes that fall within the spirit and the scope of the invention, as defined by the claims and equivalents thereof.

What is claimed is:

1. A method of manufacturing an integrated circuit by photolithographic patterning using polarized light, the method comprising:
transmitting light through a mask having a first area with a first class of patterns and a second area with a second class of patterns, thereby generating a virtual image; and
exposing the virtual image into a resist layer;
wherein a polarization of the light passing the first area is modified while the light passes the mask.

2. The method according to claim 1, wherein the modification of the polarization is a transformation into circular polarized light.

3. The method according to claim 1, wherein the modification of the polarization is a transformation into elliptical polarized light.

4. A photolithographic imaging system for manufacturing integrated circuits with a light source for polarized light and an optical imaging system, the photolithographic imaging system having a photomask comprising a first area with a first class of patterns and a second area with a second class of patterns, wherein the first area of the mask comprises chiral elements.

5. The photolithographic imaging system according to claim 4, wherein the chiral elements realize a phase shift of λ/4 between axes of birefringement.

6. The photolithographic imaging system according to claim 4, wherein the chiral elements realize a phase shift of approximately λ/4 between axes of birefringement.

7. The photolithographic imaging system according to claim 6, wherein the second area of the mask comprises achiral, phase shifting elements.

8. A photomask for processing photolithography, the photomask comprising:
a mask carrier with a first area having a first class of absorber patterns and a second area with a second class of absorber patterns, wherein a chiral layer is disposed between the absorber patterns of the first class.

9. The photomask according to claim 8, wherein the absorber patterns include an opaque absorber material.

10. The photomask according to claim 9, wherein the opaque absorber material comprises Cr.

11. The photomask according to claim 8, wherein the absorber patterns include a semitransparent, phase shifting material.

12. The photomask according to claim 11, wherein the semitransparent phase shifting material comprises MoSi.

13. The photomask according to claim 9, wherein the chiral layer realizes a phase shift of λ/4 between axes of birefringement.

14. The photomask according to claim 9, wherein the chiral layer realizes a phase shift of approximately λ/4 between axes of birefringement.

15. The photomask according to claim 14, wherein a transparent, achiral, phase shifting layer is disposed between the absorber patterns of the second class.

16. The photomask according to claim 11, wherein a transparent, achiral, phase shifting layer is disposed between the absorber patterns of the second class and a transparent, chiral, phase shifting layer is disposed on top of all the absorber patterns.

17. The photomask according to claim 8, wherein the chiral layer is disposed between the mask carrier and the absorber patterns across the whole mask.

18. The photomask according to claim 17, wherein the chiral layer realizes a phase shift of λ/4 between axes of birefringement.

19. The photomask according to claim 8, wherein the chiral layer is disposed all over a mask such that, a phase shift of approximately λ/4 is realized between axes of birefringement and the difference to λ/4 is compensated between the absorber patterns of the second class.

20. A method for fabricating a photomask, the method comprising:
forming a layer of an absorber material;
patterning the absorber layer to create a first area with patterns of a first class and a second area with patterns of a second class; and
forming a layer of a chiral material within the first area.

21. The method according to claim 20, wherein the layer of absorber material includes an opaque material.

22. The method according to claim 20, wherein the layer of absorber material includes a semitransparent phase shifting material.

23. A mask blank for a photomask having a mask carrier, the mask blank comprising:
an absorber layer; and
a chiral layer adjacent the layer of absorber material.

24. The mask blank according to claim 23, wherein the chiral layer causes a phase shift of λ/4 between axes of birefringement.

25. The mask blank according to claim 23, wherein the chiral layer causes a phase shift of approximately λ/4 between axes of birefringement.
